(19) United States
(12) Patent Application Publication
(10) Pub. No.: US 2017/0342594 A1
(43) Pub. Date: Nov. 30, 2017

(54) CHEMICAL VAPOUR DEPOSITION REACTOR

(71) Applicant: Saint-Gobain Lumilog, Courbevoie (FR)

(72) Inventors: Bernard Beaumont, Le Tignet (FR); Manivannane Pourouchottamane, Chelles (FR)

(73) Assignee: Saint-Gobain Lumilog, Courbevoie (FR)

(21) Appl. No.: 15/536,245

(22) PCT Filed: Dec. 16, 2015
(86) PCT No.: PCT/FR2015/053554

§ 371 Date: Jun. 15, 2017

(30) Foreign Application Priority Data
Dec. 16, 2014 (FR) 1462521

(51) Int. Cl. C30B 25/14; C30B 29/40; C23C 16/44; B01J 4/00; C23C 16/30; F15D 1/08; C23C 16/455

(52) U.S. Cl. CPC C30B 25/14; F15D 1/08; C30B 29/406; C23C 16/45506; B01J 4/002; C23C 16/303; C23C 16/4404; B01J 2204/005

(57) ABSTRACT

The invention concerns a reactor for chemical vapour deposition from first and second precursor gases, the reactor comprising: —a chamber including top and bottom walls and a side wall linking the top and bottom walls, —a support intended for receiving at least one substrate, mounted inside the chamber, and —at least one system for injecting precursor gases, the system comprising an injection head including at least one nozzle for supplying the first precursor gas (41) in a main direction of axis A-A′, the at least one nozzle including: a precursor gas supply conduit (321), and an outlet member (322) generating a substantially annular 43 vortex flow (44) around axis A-A′.

### TECHNICAL FIELD

The invention relates to the general technical field of chemical vapor deposition reactors.

Such reactors are for example used for manufacturing semi-conductor materials based on elements of columns 13 and 15 of the periodic table—such as gallium nitride GaN.

The invention notably relates to a chemical vapor deposition reactor for the manufacturing of wafers of element 13 nitride by injection of gas precursors.

These wafers may be intended for the manufacturing of semi-conductor structures such as light-emitting diodes (LED) or laser diodes (LD).

### PRESENTATION OF THE PRIOR ART

Present methods for manufacturing semi-conducting materials based on element 13 nitride are based on chemical vapor deposition techniques, such as deposition techniques:
by MetalOrganic Vapor Phase Epitaxy (MOVPE),
by Hydride Vapor Phase Epitaxy (HVPE),
by Close-Spaced Vapor Transport (CSVT), etc.

In order to apply these different techniques, a chemical vapor deposition reactor is generally used.

This reactor comprises a support—or “a susceptor”—intended for receiving one (or several) initial substrate(s) on which the semi-conducting material(s) is (are) manufactured.

In order to form semi-conducting material(s), precursor gases are injected into an enclosure of the reactor so as to sweep the surface of the substrate(s). These precursor gases react to the surface of the substrate(s) in order to form one (or several) layer(s) of semi-conducting material.

In order to guarantee performances of good quality in the thereby formed semi-conducting material(s), it is necessary to control the composition. Notably, the making of a uniform layer is conditioned by a laminar flow of the precursor gases on the substrate(s).

Now the precursor gases may react together and be deposited in unsuitable areas of the reactor, such as the walls of the enclosure, or the outlet of the nozzles for supplying precursor gases.

Such depositions may induce partial or total blocking of the supply nozzles, which makes the control of the flows of precursor gases difficult and therefore degrades the quality of the obtained semi-conducting materials.

Document US2008/0163816 describes a reactor including a system for injecting precursor gases for producing an AlN layer by a chemical vapor deposition method in order to homogenize the pressure exerted by the film formed on the substrate. The injection system includes an “injection shower” (referenced as 15) positioned above the substrate. The shower with a frustoconical shape is supplied via a conduit in an upper portion (reference 14). It comprises a large number of injectors (referenced as 15b) in the lower portion. However such a reactor is not adapted to depositions of gallium nitride because of the strong reactivity of the precursor gases (i.e. gallium chloride and ammonia) used for forming a layer of gallium nitride.

Document EP 0 687 749 describes a device wherein two precursor gases are injected separately just above the substrate in order to promote the homogeneity of the mixture of precursor gases and to obtain a layer of gallium nitride of good quality. These gases are in particular tri-ethyl gallium or tri-methyl gallium and ammonia. The thereby described device includes a cooling chamber (referenced as 20) which gives the possibility of avoiding a too strong reaction before the deposition. This configuration aims at improving the control of the homogeneity of the mixture of precursor gases (cf. page 4 column 6 lines 3 to 25 of EP 0 687 749). Such a device including a cooling chamber is:
difficult or even impossible to apply when the injection device is in an area of the chamber at a very high temperature (>700° C.),
expensive, and
energy consuming.

Another injection device is described in WO 2008/064083. The document proposes to make a GaN layer by HVPE on a substrate heated to 1,000° C. A sweeping gas, in this case nitrogen, is propelled laterally relatively to the substrate. A first precursor gas—i.e. gallium chloride—is provided as a dimer in a first tubing (referenced as 323) and opens into a funnel (referenced as 325) filled with silicon carbide beads SiC for which the temperature is of the order of 800° C. for decomposing the first precursor gas into a monomer. The first precursor gas decompose into a monomer is then maintained at a temperature above 600° C. in order to avoid the reformation of dimers, and is transported as far as a slot (referenced as 329) (cf. last paragraph of page 23 and first paragraph of page 24; FIGS. 4 to 6). A second precursor gas, in this case ammonia, is injected separately through a tubing (referenced as 519). The precursor gases are blown so as to follow non-turbulent conditions and at a sufficiently large distance from the substrate so that their temperature is of the order from 400 to 500° C. in order to avoid a sparse deposition in the injection device. A drawback of such an injection device is that the control of the temperature of the precursor gases is delicate, notably in the case of producing semi-conducting materials of large dimensions.

Document FR 2 957 939 describes a device for injecting gases into a treatment chamber. The injector comprises at least two adjacent injectors. Each injector comprises a diffusion plate comprising a plurality of openings for letting through the gas. A first gas wave is introduced into a first injector. In the treatment chamber, the first gas wave reacts with a substrate before being purged from the chamber by means of a discharge device. A second gas wave is then introduced into a second injector, which reacts with the deposits left by the first gas injection.

The precursor gases are therefore injected separately, it is not possible to directly proceed with the deposition of a layer of a mixture of precursor gases. The pulse/purge steps therefore have to be repeated as many times as necessary in order to obtain the desired thickness of the thin layer, which causes a relatively low production capacity.

Therefore there exists a need for a device which is still more productive giving the possibility of producing in a more stable way very homogeneous slices of a semi-conducting material, notably slices of a material nitride of element 13 of the periodic classification, more particularly slices consisting of GaN, of large size (four inches, six inches or eight inches).

### SUMMARY OF THE INVENTION

For this purpose, the invention proposes a chemical phase deposition reactor from first and second precursor gases, the reactor comprising:
an enclosure including upper and lower walls and a side wall connecting the upper and lower walls,
a support intended to receive at least one substrate, mounted inside the enclosure, and
at least one system for injecting precursor gases, the system including an injection head including at least one nozzle for supplying the first precursor gas along a main direction of axis A-A′, said at least one nozzle including:
   a precursor gas supply conduit, and
   an outlet member generating a vortex flow of a substantially annular shape around the axis A-A′.

Within the scope of the present invention, by “vortex flow with a substantially annular shape”, is meant a generally toroidal vortex wherein the flow of fluid is mainly a rotation around a curved loop itself and extending around the axis A-A′. Such a closed loop is not necessarily planar and may have different radii of curvature piece wise.

The generation of a vortex flow with a substantially annular shape around the axis A-A′ allows recirculation of the precursor gas in the vicinity of the outlet of the nozzle in order to avoid the deposition of material in the vicinity of the outlet of the nozzle by reaction of the first and second precursor gases.

Indeed, unlike what may be expected, the local recirculation of the first precursor gas does not produce any Venturi effect tending to suck up the second precursor gas.

On the contrary, in practice, the “recirculation loop” of the first precursor gas pushes back the second precursor gas and thereby avoids a reaction between both gases in the close vicinity of the outlet of the nozzle.

Preferred but non-limiting aspects of the reactor according to the invention are the following.

The outlet member may comprise an upstream end facing the precursor gas supply conduit and a downstream end opposite to the upstream end along the main direction, the sectional dimensions of the upstream end being less than the sectional dimensions of the downstream end.

The variations of sections between the upstream and downstream end portions of the outlet member give the possibility of generating a vortex flow around the outlet of the supply nozzle. Alternatively, the upstream and downstream ends of the outlet member may have equal sections, the outlet member including an annular striction (or shrinkage) between the upstream and downstream ends, this striction generating local acceleration of the ejected gas just before passing at the annular striction and generating a vortex flow just after the striction.

The outlet member may consist in a part connected to the outlet of the gas supply conduit. Alternatively, the outlet member and the gas supply conduit may be in a single piece. Notably, the outlet member may comprise a coaxial recess with the gas supply conduit.

This gives the possibility of obtaining a supply nozzle wherein the downstream end of the outlet member is flushed with the surface of the injection head.

Advantageously, the recess may comprise a cylindrical counterbore, the diameter of the counterbore being greater than the diameter of the precursor gas supply conduit.

This gives the possibility of facilitating the manufacturing of the injection head, a simple piercing of the nozzles at their free end giving the possibility of forming the outlet members.

The recess may comprise a flared portion outwards along the main direction A-A′.

This gives the possibility, in the supply nozzle, of limiting the regions which may induce pressure losses for the vortex flow.

In an alternative embodiment, the recess may also include a frustoconical portion.

This gives the possibility of obtaining a vortex wherein the flow velocities of the fluid are uniformly distributed around the outlet of the nozzle.

In another alternative embodiment, the recess may include a concave portion, notably with the shape of a piece of a torus.

This gives the possibility of accelerating the velocities of rotation of the fluid so in the vortex.

The recess may also comprise a combination of portions of different shapes.

In an embodiment, the walls of the outlet member comprise a molybdenum coating. This gives the possibility of protecting the walls of the outlet member against deposition of gallium nitride.

The injection head may be used for introducing a single one of the precursor gases required for the deposition reaction. Alternatively, the injection head may be laid out so as to allow the introduction of different precursor gases. In this case, it may comprise:
a plurality of first nozzles for supplying a first precursor gas,
a plurality of second nozzles for supplying a second precursor gas,
   the first and second nozzles being alternatively distributed in the injection head.

By distributing the first and second nozzles alternatively gives the possibility of ensuring a more homogeneous distribution of the precursor gases at the surface of the substrate on which the deposition has to be applied.

Preferably, the largest dimension in section of the outlet member is greater than the largest dimension in section of the gas supply conduit, and the ratio between the largest dimension in section of the outlet member and the depth of the outlet member is comprised between 0.1 and 10. These dimensions are more particularly adapted for the manufacturing of semi-conducting materials including one (or several) layer(s) of gallium nitride.

The invention also relates to a method for manufacturing a semi-conducting material in a chemical vapor deposition reactor as described above, the method comprising an applied epitaxial growth step:
by MetalOrganic Vapor Phase Epitaxy (MOVPE),
by Hydride Vapor Phase Epitaxy (HVPE), or
by Close-Spaced Vapor Transport (CSVT).

The invention also relates to a method for manufacturing a chemical vapor deposition reactor from first and second precursor gases, the reactor comprising:
an enclosure including upper and lower walls and a side wall connecting the so upper and lower walls,
a support intended to receive at least one substrate, mounted inside the enclosure, and
at least one system for injecting precursor gases, the system including an injection head including at least one nozzle for supplying the first precursor gas along a main direction of axis A-A′, said at least one nozzle including a precursor gas supply conduit,
   remarkable in that the method comprises a phase for dimensioning an outlet member of the nozzle, for determining the geometry of the outlet member allowing the generation of a vortex flow with a substantially annular shape around the axis A-A′.

Preferred but non-limiting aspects of the manufacturing method described above are the following:
the dimensioning phase may comprise a step for selecting a set of geometrical characteristics of the supply nozzle allowing the obtaining of a vortex flow for which the diameter is substantially equal to the depth of the outlet member,
the dimensioning phase may also comprise the following steps:
   receiving parameters relating to:
      operating conditions of the supply nozzle,
      physico-chemical characteristics of the gas intended to be ejected,
   defining a set of geometrical characteristics of the supply nozzle,
   numerical modelling of the injector from received parameters and from the defined set of geometrical characteristics;
   estimating from the modelling, geometrical characteristics of the vortex flow generated by the outlet member;
   comparing the diameter H of the vortex flow and of the depth P of the outlet member.

### SHORT DESCRIPTION OF THE DRAWINGS

Other advantages and features of the reactor according to the invention will still emerge from the description which follows, of several alternative embodiments, given as non-limiting examples, from appended drawings wherein:

FIG. 1 illustrates an example of a chemical vapor deposition reactor according to the invention,

FIG. 2 illustrates an example of a supply nozzle from the prior art,

FIG. 3 illustrates an example of a supply nozzle according to the invention,

FIG. 4 schematically illustrates various alternatives of an outlet member of a supply nozzle,

FIG. 5 is a perspective view of an injection head according to the invention,

FIG. 6 is a sectional view of an injection head and of a reactor support,

FIG. 7 is a schematic sectional illustration of an outlet member,

FIG. 8 schematically illustrates steps of a method for dimensioning an outlet member of an injection head.

### DETAILED DESCRIPTION OF THE INVENTION

Various examples of chemical vapor deposition reactors will now be described in more details with reference to the figures. In these different figures, the equivalent elements bear the same numerical references.

In the following, the invention will be described with reference to the manufacturing of gallium nitride GaN wafers.

However, it is quite obvious for one skilled in the art that the reactor described below may be used for growing a material other than gallium nitride GaN.

### 1. General

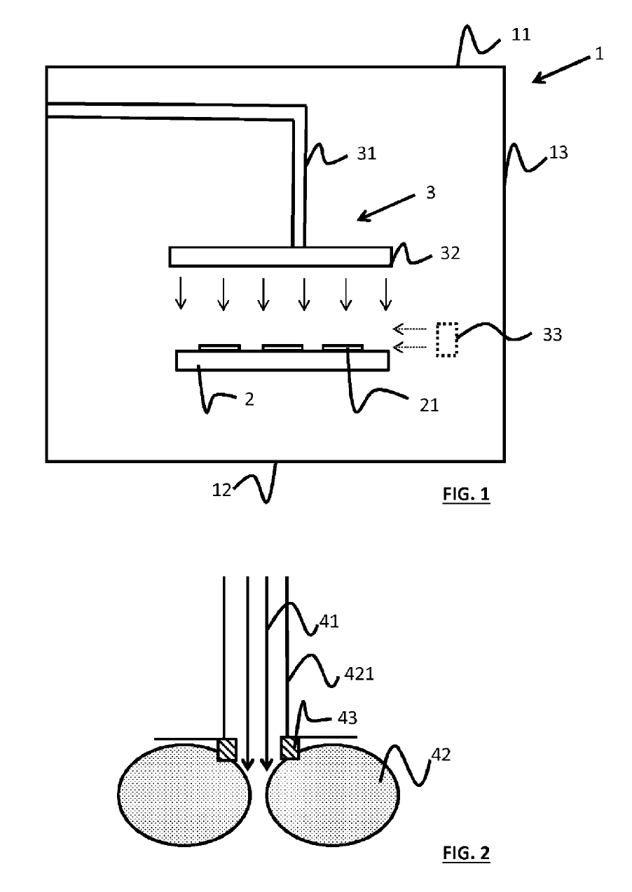

With reference to FIG. 1, an example of a chemical vapor deposition reactor is illustrated, wherein gas precursors are injected in order to allow the growth of GaN on a substrate for example of sapphire.

The reactor comprises an enclosure 1 housing a support 2 and an injector 3.

The enclosure 1 is a chamber in which the deposition is applied. It may be of a parallelepipedal or cylindrical shape (or other shape) and comprises an upper wall 11, a lower wall 12 and one (or several) side wall(s) 13.

The support 2 comprises a susceptor intended to receive one (or several) substrate(s) used for growing the layer(s) of gallium nitride GaN. This growth is obtained by reacting together two so called “gas precursors” gases—at the surface of the substrate 21.

The injector 3 opens into the inside of the enclosure 1 through an inlet orifice. The injector 3 gives the possibility of transporting the gas flow inside the enclosure 1, and notably of at least of the gas precursors required for forming the gallium nitride layer.

The injector 3 comprises one (or several) duct(s) 31 for transporting the gas flow and one (or several) injection head(s) 32. The injection head(s) 32 give the possibility of sweeping the substrate positioned on the support 2 with one (or several) chemical agent(s) in a gas phase.

The injection head 32 may be positioned above the outlet support 2 so that the gas flow is projected in a substantially perpendicular direction to the upper face of the support 2. Alternatively (or additionally), the (or one) injection head 33 may be positioned beside the support 2 so as to project the gas flow in a direction substantially parallel to the upper face of the support 2.

### 2. Particularities of the Reactor According to the Invention

2.1. Problem of the Existing Injectors

A drawback of the injectors of the prior art is that the gas precursors 41, 42 tend to react together at the supply nozzles 421. As illustrated in FIG. 2, this reaction induces the formation of a film 43 on the supply nozzles 421, this film partly obstructing or totally obstructing the supply nozzles 421. This may compromise the manufacturing of high quality components in the reactor, since it becomes difficult to control the injection parameters (such as the flow rate, the concentration, etc.) of the precursor gases 41, 42 in the enclosure 1.

2.2. Proposed Solution

In order to solve this drawback, it is necessary to avoid the reaction of the precursor gases 41, 42 at the supply nozzles of the injection head 32, 33.

To do this, the formation of an outlet member 322-328 in each supply nozzle is proposed. The function of this outlet member 322-328 is to prevent the reaction of the gas precursors 41,42 at the supply nozzles.

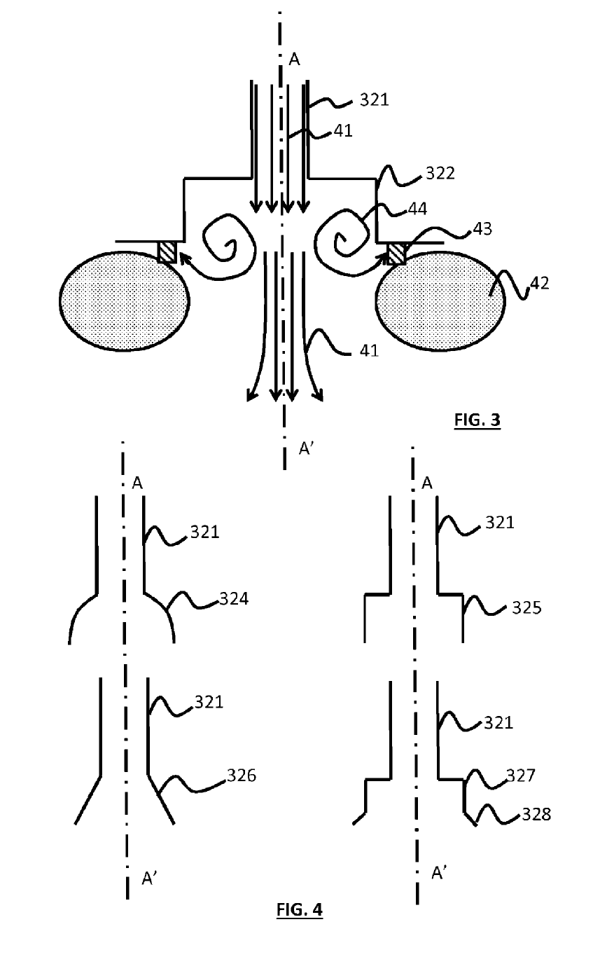

In the embodiment illustrated in FIG. 3, each supply nozzle thereby consists in:
a gas supply conduit 321 extending along an axis A-A′, and
an outlet member 322 connected to the end of the gas supply conduit 321, the outlet member 322 generating a vortex flow with a substantially annular shape around the supply conduit 321.

Thus, if the supply nozzle ejects a first precursor gas 41 into the enclosure 1 of the reactor, the outlet member 322 generates a vortex 44 of the first precursor gas 41, this vortex 44 having the shape of a torus and extending around the outlet of the supply nozzle (axis A-A′).

The fact that each injection nozzle comprises an outlet member 322 generating a toroidal flow 44 of the ejected species 41 gives the possibility of generating a recirculation of the first ejected gas precursor 41 at the outlet of the nozzle. Thus locally, the atmosphere of the enclosure 1 is enriched (i.e. in proximity to the outlet of the supply nozzle) with the ejected precursor gas 41.

This gives the possibility of preventing the formation of a film at the outlet of the supply nozzle.

Indeed, the inventors have discovered that the formation of a film of gallium nitride requires the presence of two gas precursors 41, 42 in substantially equivalent proportions: notably at concentrations of the same order of magnitude.

In this case, the fact of generating a turbulent vortex 44 of the first ejected precursor gas 41, induces a local enrichment of the atmosphere with the first ejected precursor gas 41 (and therefore local depletion of the atmosphere with the second precursor gas 42). The local concentrations of the first and second precursor gases 41, 42 being very different, the latter no longer react together at the outlet of the supply nozzle.

The risks of obturation of the supply nozzles is thereby avoided. Of course, the first and second precursor gases 41, 42 continue to react together, but in an area 43 sufficiently far from the outlet of the supply nozzle for limiting any risk of blocking the latter.

### 3. Outlet Member

3.1. Alternatives for the Outlet Member

The outlet member 322-328 may consist in a part mounted at the end of the gas supply conduit 321. In this case, the outlet member 322-328 extends by protruding outwards from the injection head 32.

Alternatively, the outlet member 322-328 and the supply conduit 321 may be in one piece. This gives the possibility of limiting the number of parts making up the injection head 32, and thereby facilitates its manufacturing.

The outlet member 322-328 may for example consist in a recess made at the free end of the gas supply conduit 321. An outlet member 322-328 is thereby obtained opening and flushed with the injection head 32 is thereby obtained. This gives the possibility of limiting the number of walls on which an undesired film 43 of gallium nitride may be deposited.

For example in the embodiment illustrated in FIG. 3, the outlet member 322 consists in a substantially cylindrical counterbore. This counterbore is obtained by making a bore in the gas supply conduit, for example by piercing.

When the outlet member consists in a shoulder, its shape may vary, notably depending:
on the type of machining applied for making the outlet member,
on the shape of the gas supply conduit 321.

With reference to FIG. 4, the outlet member may for example consist in:
a recess of a concave shape, for example as a sphere portion 324,
a recess of a parallelepipedal or cylindrical shape 325,
a recess of a frustoconical shape 326,
a recess of a complex shape consisting in a combination of the previous shapes, for example consisting of a cylindrical portion 327 and of a frustoconical portion 328.

Preferably the cross-sectional profile of each supply nozzle has a sudden variation in section between the supply conduit and the outlet member. This gives the possibility of promoting the generation of a turbulent vortex at the outlet of each supply nozzle. Thus, outlet members will be preferred with the shape of a step or a square wave in a longitudinal section.

Advantageously, the walls of the outlet member may be treated for limiting the risks of nucleation on the latter. For example, in an embodiment, the outlet member is covered with one (or several) molybdenum layer(s) (alternatively, the outlet member may consist of molybdenum). The molybdenum has actually the particularity of preventing nitridation and therefore protecting the outlet member against the risks of formation of a gallium nitride film.

3.2. Dimensions of the Outlet Member

The dimensions of the outlet member depend on different parameters, and notably on relative parameters:
to the geometry of the injector,
to the type of ejected precursor gas by the supply nozzle,
to the conditions of use of the injector (flow rate of the ejected precursor gas, temperature, . . . ), etc.

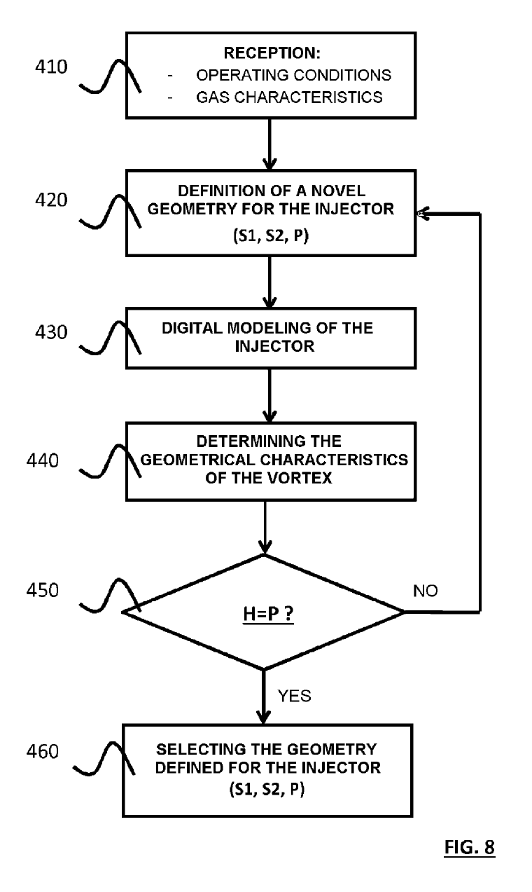

With reference to FIG. 8, the steps of a method for dimensioning an outlet member of a supply nozzle have been illustrated. This dimensioning method may advantageously be applied within the scope of a method for manufacturing the chemical vapor deposition reactor described above.

The dimensioning method consists of determining the geometry of the outlet member allowing the generation of a sufficient vortex flow in order to avoid the deposition of material in the vicinity of the outlet of the supply nozzle.

Notably, the dimensioning method gives the possibility of defining the geometrical characteristics of the outlet member allowing the obtaining of a vortex flow for which the diameter is substantially equal to the depth (i.e. the dimension of the outlet member along the axis A-A′) of the outlet member.

The dimensioning method may comprise the following steps:
a) receiving (410) parameters relating to:
   operating conditions of the supply nozzle, such as the pressure, the temperature and the mass flow rate(s) of the ejected gas(es) (notably the precursor gas, the carrier gas, etc.),
   physico-chemical characteristics of the ejected gas(es) (pyrolysis, viscosity, etc.);
b) defining (420) a set of geometrical characteristics of the injection head, and notably of the relevant supply nozzle, the geometrical characteristics for example relating to
   the section S1 of the gas supply conduit,
   the length—i.e. the largest dimension along a direction perpendicular to the axis A-A′—(or section S2 in the case of a counterbore) of the outlet member,
   the depth P of the outlet member,
c) numerical modeling (430) of the injector in its environment from parameters received in step a) and from the set of geometrical characteristics defined in step b);
d) estimating (440), from the modeling, the geometrical characteristics of the vortex flow generated by the outlet member;
e) comparing (450) the diameter H of the vortex flow and the depth P of the outlet member, and
   If the diameter H is equal to the depth P, the selection (460) of the set of geometrical characteristics defined in step b), and the stopping of the method,
   If the diameter H is different from the depth P, repeating steps b) to e) of the method for a new set of geometrical characteristics different from the set of current geometrical characteristics.

Thus, the dimensions of the outlet member may vary depending on the type of ejected precursor gas by the supply nozzle, and/or on the ejection velocity of the gas, and/or on the concentration of the gas, etc.

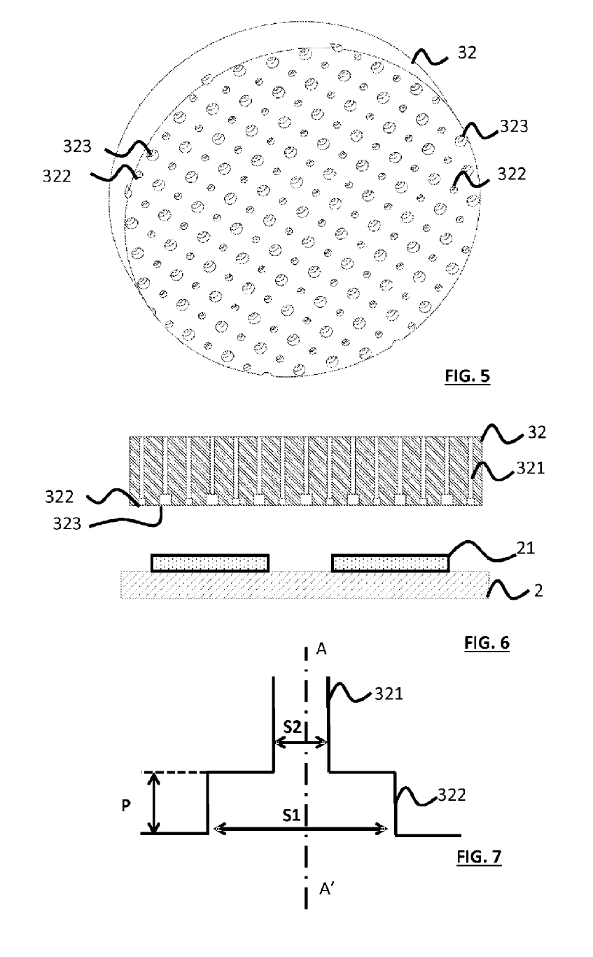

This is why when the injection head is adapted for injecting two different gas precursors into the enclosure, the latter may comprise outlet members of different dimensions, as illustrated in FIGS. 5 and 6.

In this embodiment, the injection head comprises:
a plurality of first supply nozzles for a first precursor gas 41,
a plurality of second supply nozzles for the second precursor gas 42,

Each supply nozzle from the plurality of first supply nozzles comprises a supply channel 321 and a first outlet member 322. Each supply nozzle from the plurality of second supply nozzles comprises a supply channel 321 and a second outlet member 323.

The first and second outlet members 322, 323 are cylindrical counterbores and have different dimensions. Notably, the diameter and the depth of each first outlet member 322 are respectively less than the diameter and less than the depth of each second outlet member 323.

Preferably, the first and second supply nozzles are alternately positioned on the injection head. Thus, each first supply nozzle is adjacent to two second supply nozzles along a diameter of the injection head as illustrated in FIG. 5. This gives the possibility of a better distribution of the two precursor gases at the surface of the substrate(s) positioned on the support of the reactor.

3.3. Dimensioning of the Outlet Member

The tests and modellings give the possibility of dimensioning each outlet member in an optimal way. In particular, in the case of an outlet member consisting in a cylindrical recess, the depth P and the section S1 of the recess may be estimated notably by taking into account:
the section S2 of the supply conduit 321,
the dynamic viscosity of the precursor gas to be ejected, and
the flow rate of each gas under the temperature and pressure conditions of the reactor.

Thus for a hole for injecting gallium chloride diffused in a hydrogen carrier gas, one has the following relationship:

P=(2.95×10⁻³*(18*D_{GaCl}+D_{H2})−0.35)*[(S1/S2)²−S1/S2]

Wherein:
D_{GaCl} is the mass flow rate of gallium chloride in the injector of section S2 and
D_{H2} is the mass flow rate of hydrogen in the injector of section S2.

For a hole for injecting ammonia, diffused in a hydrogen carrier gas, one has the following relationship:

P=(3.80×10⁻³*(8.33*D_{NH3}+D_{H2})−0.45)*[(S1/S2)²−S1/S2]

Wherein:
D_{GaCl} is the mass flow rate of gallium chloride in the injector of section S2, and
D_{H2} is the mass flow rate of hydrogen in the injector of section S1.

Thus for example, it is possible to generate for a mixed flow rate of 30 sccm of ammonia and of 10 sccm of hydrogen an optimal recirculation of gas with an injector for which the supply conduit is of a circular section with a diameter of 2 mm, enlarged to a section of 4 mm at the outlet member by selecting a depth of 4 mm, the chamber temperature being comprised between 850 and 1,000° C.

Preferably in the case of a circular counterbore, the outlet member is with a diameter comprised between 2 and 10 millimeters and a depth comprised between 4 and 20 millimeters when the gas supply conduit 321 has a diameter comprised between 1 and 5 millimeters.

The reader will have understood that many modifications may be made to the reactor described above.

For example, the shape of the outlet member is not limited to a cylinder or a shape having axisymmetry, the latter may notably be rectangular or elliptical, etc.

1. A chemical vapor deposition reactor from first and second precursor gases (41, 42), the reactor comprising:
an enclosure (1) including upper (11) and lower (12) walls and a side wall (13) connecting the upper (11) and lower (12) walls,
a support (2) intended to receive at least one substrate (21), mounted inside the enclosure (1), and
at least one system (31, 32) for injecting precursor gases, the system (31, 32) including an injection head (32) including a plurality of first nozzles for supplying the first precursor gas (41) along a main direction of axis A-A′, one nozzle including:
a precursor gas supply conduit (321), and
an outlet member (322) dimensioned for generating a vortex flow (44) of a substantially annular shape around the axis A-A′.

2. The reactor according to claim 1 wherein the outlet member comprises an upstream end facing the precursor gas supply conduit and a downstream end opposite to the upstream end along the main direction, the sectional dimensions of the upstream end being less than the sectional dimensions of the downstream end.

3. The reactor according to claim 1, wherein the outlet member comprises a coaxial recess with the gas supply conduit.

4. The reactor according to claim 3, wherein the recess comprises a cylindrical counterbore, the diameter of the counterbore being greater than the diameter of the precursor gas supply conduit.

5. The reactor according to any one of claim 3 or 4, wherein the recess comprises a flared portion outwards along the main direction.

6. The reactor according to claim 3 to 5, wherein the recess includes a frustoconical portion (326).

7. The reactor according to any one of claims 3 to 6, wherein the recess includes a concave portion, notably with the shape of a piece of a torus (324).

8. The reactor according to any one of the preceding claims, wherein the walls of the outlet member comprise a molybdenum coating.

9. The reactor according to any one of the preceding claims, wherein the injection head comprises:
a plurality of second supply nozzles (321, 323) for the second precursor gas,
the first and second nozzles being alternately distributed in the injection head.

10. A method for manufacturing a semi-conducting material in a chemical vapor phase deposition reactor according to any one of claims 1 to 9, the method comprising an applied epitaxial growth step:
by MetalOrganic Vapor Phase Epitaxy (MOVPE),
by Hydride Vapor Phase Epitaxy (HVPE), or
by Close-Spaced Vapor Transport (CSVT).

11. The method for manufacturing a chemical phase deposition reactor from first and second precursor gases (41, 42), the reactor comprising:
an enclosure (1) including upper (11) and lower (12) walls and a side wall (13) connecting the upper (11) and lower (12) walls,
a support (2) intended to receive at least one substrate (21), mounted inside the enclosure (1), and
at least one system (31, 32) for injecting precursor gases, the system (31, 32) including an injection head (32) including at least one nozzle for supplying the first precursor gas (41) along a main direction of axis A-A′, said at least one nozzle including a precursor gas supply conduit (321), characterized in that the method comprises a phase for dimensioning an outlet member of the nozzle, for determining the geometry of the outlet member allowing the generation of a vortex flow (44) with a substantially annular shape around the axis A-A′.

12. The manufacturing method according to claim 11, wherein the dimensioning phase comprises a step for selecting a set of geometrical characteristics of the supply nozzle allowing the obtaining of a vortex flow for which the diameter is substantially equal to the depth of the outlet member.

13. The manufacturing method according to claim 12, wherein the dimensioning phase comprises the following steps:
a) receiving (410) parameters relating to:
operating conditions of the supply nozzle,
physico-chemical characteristics of the gas intended to be ejected,
b) defining (420) a set of geometrical characteristics of the supply nozzle,
c) numerical modelling (430) of the injector from received parameters and from the defined set of geometrical characteristics;
d) estimating (440) from the modelling, geometrical characteristics of the vortex flow generated by the outlet member;
e) comparing (450) the diameter H of the vortex flow and of the depth P of the outlet member.
